(19) United States
(12) Patent Application Publication
(10) Pub. No.: US 2016/0013251 A1
(43) Pub. Date: Jan. 14, 2016

(54) EL DISPLAY DEVICE

(71) Applicant: JOLED INC., Chiyoda-ku, Tokyo (JP)

(72) Inventors: Hideki YOSHIDA, Osaka (JP); Yoichi SHINTANI, Tokyo (JP)

(73) Assignee: JOLED INC., Tokyo (JP)

(21) Appl. No.: 14/772,103

(22) PCT Filed: Aug. 20, 2013
(86) PCT No.: PCT/JP2013/004907

§ 371 Date: Sep. 2, 2015

(30) Foreign Application Priority Data
Mar. 4, 2013 (JP) 2013-041516

(51) Int. Cl. H01L 27/32

(52) U.S. Cl. CPC H01L 27/3216; H01L 27/3246

(57) ABSTRACT

An EL display device according to the present technology includes a light emitter in which an array of pixels are arranged, each of the pixels including sub-pixels configured to emit at least red, green, and blue light; and a thin film transistor array configured to control light emission of the light emitter. The sub-pixels include light-emitting layers, the light-emitting layers being configured to emit at least red, green, and blue light and being disposed within areas defined by a bank having a lattice shape. Among the sub-pixels, sub-pixels that are adjacent and configured to emit identical colors include one of the light-emitting layers disposed within a first coupled bank area, the first coupled bank area corresponding to an area defined by the bank of two of the sub-pixels.

### TECHNICAL FIELD

The present technology is related to electroluminescence (EL) display devices.

### BACKGROUND ART

Recently, next generation display devices are being actively developed, and EL display devices that have a first electrode, a plurality of organic layers including a light-emitting layer, and a second electrode layered in order on a driving substrate are attracting attention. EL display devices have features such as self-generated light emission and therefore a wide viewing angle, no backlight requirement and therefore low power consumption, high responsiveness, and properties that enable reduced device thickness. Thus, application of EL display devices to large screen display devices such as televisions is strongly desired.

For color displays, red, blue, and green three-color pixel displays are most typical, but with the aims of improved power saving and reliability, red, blue, green, and white four-color pixel displays and red, blue, green, and pale blue four-color pixel displays are being developed by various companies.

In an organic EL light-emitting element it is necessary to form an organic EL light emitter for each pixel, such as a red, blue, and green three-color organic EL light emitter or a red, blue, green, and white four-color organic EL light emitter.

The most typical manufacturing process for manufacturing individual organic EL units is by using vapor deposition into minute holes in a fine metal mask. For example, an organic EL unit emitting red light is formed by vapor deposition using a fine metal mask for red, an organic EL unit emitting green light is formed by vapor deposition using a fine metal mask for green, and an organic EL unit emitting blue light is formed by vapor deposition using a fine metal mask for blue, thereby forming a red, green, and blue light-emitter.

However, to form large organic EL light-emitting elements and reduce costs, development of organic EL light-emitting element technology using large substrates is of importance.

Recently, two methods of forming organic EL light-emitting elements using large substrates are attracting attention.

A first method is a method of forming white organic EL elements in all display areas and achieving a color display by using a red, green, blue, and white four-color color filter. This method is effective in forming large screens and high-definition displays.

Another method is a coating method of forming organic EL light emitters. As coating methods, various manufacturing methods have been considered. They can be roughly classified into methods using relief printing, flexographic printing, screen printing, gravure printing, etc., and methods using inkjet printing (see Patent Literature 1).

### CITATION LIST

### Patent Literature

Patent Literature 1: Japanese Patent Application Publication 2011-249089

### SUMMARY OF INVENTION

An EL display device according to the present technology includes a light emitter in which an array of pixels are arranged, each of the pixels including sub-pixels configured to emit at least red, green, and blue light; and a thin film transistor array configured to control light emission of the light emitter. The sub-pixels include light-emitting layers, the light-emitting layers being configured to emit at least red, green, and blue light and being disposed within areas defined by a bank having a lattice shape. Among the sub-pixels, sub-pixels that are adjacent and configured to emit identical colors include one of the light-emitting layers disposed within a coupled bank area, the coupled bank area corresponding to an area defined by the bank of at least two of the sub-pixels.

According to the present technology, an inkjet method can be applied to manufacture of a large screen EL display device and variation in luminance efficiency of each sub-pixel is suppressed, achieving the EL display device that allows high definition.

### BRIEF DESCRIPTION OF DRAWINGS

FIG. 1 is a perspective view of an organic EL display device according to one embodiment of the present technology.

FIG. 2 is an electrical schematic illustrating configuration of a pixel circuit.

FIG. 3 is a cross-section illustrating configuration of RGB pixel portions in an EL display device.

FIG. 4 is a diagram illustrating an arrangement of sub-pixels within pixels in an EL display device according to one embodiment of the present technology.

FIG. 5 is a diagram illustrating an arrangement of sub-pixels within pixels in an EL display device according to another embodiment of the present technology.

FIG. 6 is a diagram illustrating an arrangement of sub-pixels within pixels in an EL display device according to another embodiment of the present technology.

FIG. 7 is a diagram illustrating an arrangement of sub-pixels within pixels in an EL display device according to another embodiment of the present technology.

FIG. 8 is a diagram illustrating an arrangement of sub-pixels within pixels in an EL display device according to another embodiment of the present technology.

### EMBODIMENTS

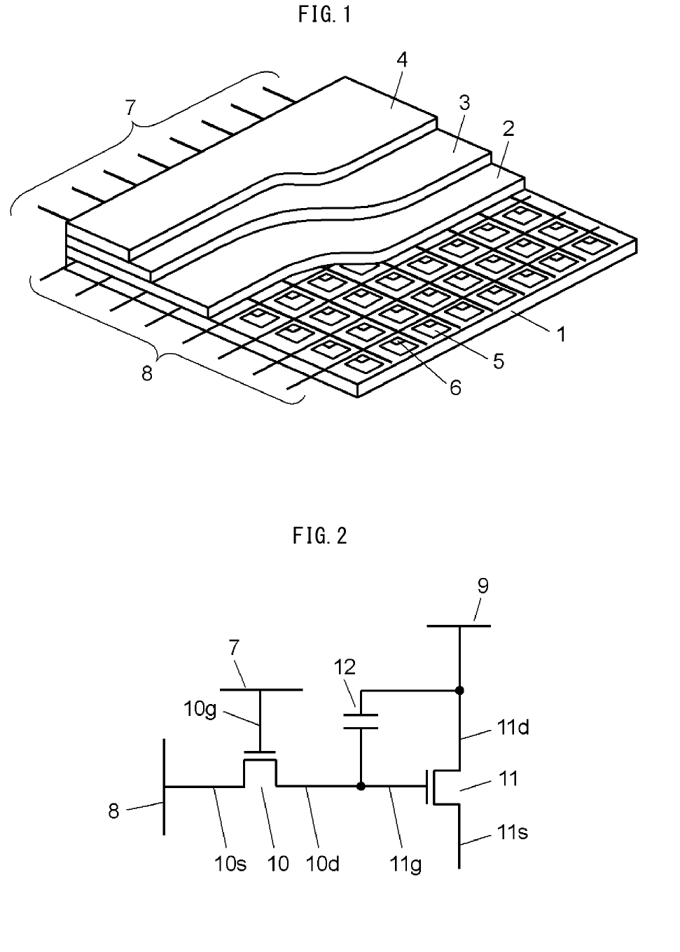

The following is a description of a method of manufacturing an EL display device according to one embodiment of the present technology, with reference to FIGS. 1-4. However, detailed description over and above what is necessary may be omitted. For example, detailed description of well-known matters and overlapping explanation of substantially identical configurations may be omitted. This avoids unnecessary redundancy in description and aids understanding for a person having ordinary skill in the art.

The inventors have provided drawings and the following description so that a person having ordinary skill in the art may sufficiently understand the present technology, but the drawing and the following description are not intended to limit the subject matter described in the claims.

FIG. 1 is a perspective view illustrating a schematic configuration of the EL display device, and FIG. 2 is a diagram illustrating a circuit configuration of a pixel circuit that drives a pixel.

FIG. 1 and FIG. 2 relate to the EL display device, the EL display device including a thin film transistor array 1 and a light emitter. The light emitter is composed of an anode 2 that is a bottom electrode, a light-emitting layer 3 composed of organic material, and a cathode 4 that is a light-transmissive upper electrode. Light emission of the light emitter is controlled by the thin film transistor array 1. The light emitter has a structure such that the light-emitting layer 3 is disposed between the anode 2 and the cathode 4, which are a pair of electrodes. A hole transport layer is formed between the anode 2 and the light-emitting layer 3, and an electron transport layer is formed between the light-emitting layer 3 and the cathode 4. A plurality of pixels 5 is arranged in a matrix in the thin film transistor array 1.

Each of the pixels 5 is driven by a corresponding one of pixel circuits 6. The thin film transistor array 1 includes a plurality of gate lines 7 arranged in rows, a plurality of source lines 8 as signal lines arranged in columns perpendicular to the gate lines 7, and a plurality of power supply lines 9 that extend parallel to the source lines 8 (not illustrated in FIG. 1).

Each row of the gate lines 7 is connected to gate electrodes 10g of thin film transistors 10 that operate as switching elements in the pixel circuits 6, the switching elements being provided to the pixel circuits 6 on a one-to-one basis. Each column of the source lines 8 is connected to source electrodes 10s of the thin film transistors 10 that operate as switching elements in the pixel circuits 6, the switching elements being provided to the pixel circuits 6 on a one-to-one basis. Each row of the power supply lines 9 is connected to drain electrodes 11d of thin film transistors 11 that operate as drive elements in the pixel circuits 6, the drive elements being provided to the pixel circuits 6 on a one-to-one basis.

As illustrated in FIG. 2, a given one of the pixel circuits 6 includes one of the thin film transistors 10 that operate as switching elements, one of the thin film transistors 11 that operate as drive elements, and one of capacitors 12 that store data to be displayed at corresponding pixels.

The one of the thin film transistors 10 includes: one of the gate electrodes 10g connected to one of the gate lines 7; one of the source electrodes 10s connected to one of the source lines 8; one of the drain electrodes 10d connected to one of the capacitors 12 and one of the gate electrodes 11g of one of the thin film transistors 11; and a semiconductor film (not illustrated). When voltage is applied to the one of the gate lines 7 and the one of the source lines 8 connected to the one of the thin film transistors 10, a voltage value applied to the one of the source lines 8 is stored as display data in the one of the capacitors 12.

The one of the thin film transistors 11 includes: the one of the gate electrodes 11g connected to the one of the drain electrodes 10d of the one of the thin film transistors 10; one of the drain electrodes 11d connected to one of the power supply lines 9 and the one of the capacitors 12; one of the source electrodes 11s connected to the anode 2; and a semiconductor film (not illustrated). The one of the thin film transistors 11 supplies, to the anode 2, a current corresponding to the voltage value stored by the one of the capacitors 12, from the one of the power supply lines 9, via the one of the source electrodes 11s. In other words, the EL display device having the above configuration adopts an active matrix scheme performing display control for each of the pixels 5 positioned at intersections of the gate lines 7 and the source lines 8.

In the EL display device, a light emitter emitting at least red, green, and blue light is formed from sub-pixels having at least red (R), green (G), and blue (B) light-emitting layers, arranged in a plurality of matrices to form a plurality of pixels. Sub-pixels composing each pixel are separated from each other by a bank. The bank is formed so that ridges extending parallel to the gate lines 7 and ridges extending parallel to the source lines 8 intersect with each other. Thus, sub-pixels having RGB light-emitting layers are formed in portions surrounded by these ridges, i.e. openings of the bank.

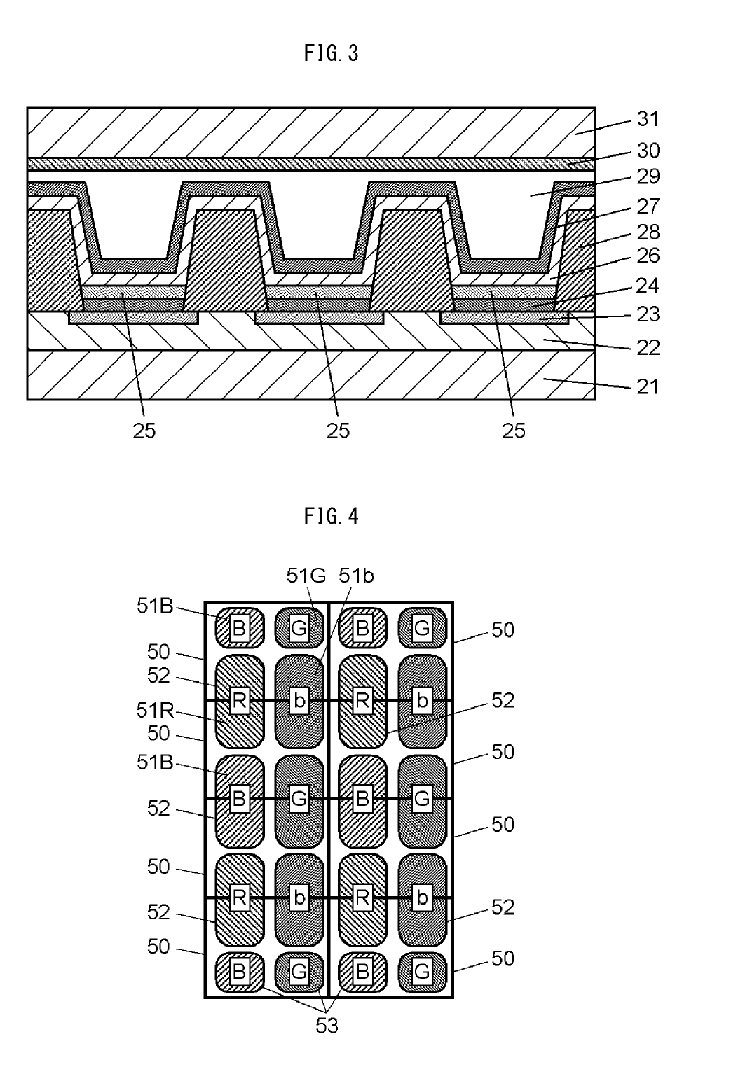

FIG. 3 is a cross-section illustrating configuration of RGB sub-pixel portions in the EL display device. As illustrated in FIG. 3, in the EL display device, the thin film transistor array 22 including the pixel circuits 6 described above is formed on a base substrate 21 such as a glass substrate or a flexible resin substrate. Further, the anode 23, which is a bottom electrode, is formed on the thin film transistor array 22 with a planarized insulating film (not illustrated) therebetween. The hole transport layer 24, the light-emitting layer 25 composed of organic material and emitting RGB light, the electron transport layer 26, and the cathode 27 that is a light-transmissive upper electrode are layered on the anode 23, thus forming an RGB organic EL light emitter.

The light-emitting layer 25 of the light emitter is formed in areas divided up by the bank 28, which is an insulating layer. The bank 28 is for dividing up light emission areas into predefined shapes while maintaining insulation between the anode 23 and the cathode 27, and is formed from, for example, a photosensitive resin such as silicon oxide or polyimide.

In the embodiment above, only the hole transport layer 24 and the electron transport layer 26 are illustrated, but a hole injection layer and an electron injection layer are layered on the hole transport layer 24 and the electron transport layer 26, respectively.

A light emitter configured in this way is covered by a sealing layer 29 such as silicon nitride and further sealed by a sealing substrate 31 such as a light-transmissive glass substrate or light-transmissive flexible resin substrate adhered over a whole surface, with an adhesive layer 30 between the sealing layer 29 and the sealing substrate 31.

Shape, material, size, etc., of the base substrate 21 is not specifically limited, and appropriate selection may be made according to purpose. For example, the base substrate 21 may be a glass material such as alkali-free glass or soda glass, a silicon substrate, or a metal substrate. Further, a polymer-based material may be used for purposes of weight reduction and flexibility. As a polymer-based material, polyethylene terephthalate, polycarbonate, polyethylene naphthalate, polyimide, polyimide, etc., is suitable, but other known polymer substrate material may be used such as other acetate resins, acrylic resins, polyethylene, polypropylene, and polyvinyl chloride resin. When a polymer-based material is used as a substrate, a method of manufacturing is used whereby, after a polymer substrate is coated, adhered, etc., on a material having stiffness such as glass, the organic EL light-emitting element is formed, and subsequently the material having stiffness such as glass is removed.

The anode 23 is formed from a metal material having high electrical conductivity such as aluminium, an aluminium alloy, or copper; a metal oxide having high electrical conductivity such as light-transmissive IZO, ITO, tin oxide, indium oxide, or zinc oxide; a metal sulfide; etc. As a method of film formation, methods of forming thin films may be used, such as vacuum deposition, sputtering and ion plating.

For the hole transport layer 24, a phthalocyanine compound such as poly(vinylcarbazole)-based material, polysilane-based material, a polysiloxane derivative, copper phthalocyanine, etc.; an aromatic amine compound; etc., is used. As a method of film formation, various coating methods are suitable, forming a layer having a thickness of approximately 10 nm to 200 nm. The hole-injection layer layered on the hole transport layer 24 is a layer for increasing hole injection from the anode 23, and is formed by sputtering of a metal oxide such as molybdenum oxide, vanadium oxide, aluminium oxide, etc.; a metal nitride; or a metal oxide nitride.

The light-emitting layer 25 is mainly composed of an organic material that emits light, such as fluorescent or phosphorescent light, properties of which may be improved by adding a dopant as required. As a polymer-based organic material suitable for printing, a poly(vinylcarbazole) derivative, a poly(p-phenylene) derivative, a polyfluorene derivative, a polyphenylenevinylene derivative, etc., is used. A dopant is a material used for shifting a wavelength of emitted light and improving light-emitting efficiency, and many dye-based and metal complex-based dopants have been developed. When the light-emitting layer 25 is formed on a large substrate, a printing method is suitable. Among various printing methods, an inkjet method is used and the light-emitting layer 25 having a thickness of approximately 20 nm to 200 nm is formed.

For the electron transport layer 26, a material is used such as a benzoquinone derivative, a polyquinoline derivative, or an oxadiazole derivative. As a method of film formation, vacuum deposition or a coating method is used, the electron transport layer 26 typically having a thickness of approximately 10 nm to 200 nm. The electron injection layer is formed using vacuum deposition or a coating method using a material such as barium, phthalocyanine, lithium fluoride, etc.

The cathode 27 is a different material depending on a direction in which light is extracted. When light is extracted from a cathode 27 side, a light-transmissive electrically-conductive material is used such as ITO, IZO, tin oxide, zinc oxide, etc. When light is extracted from an anode 23 side, a material is used such as platinum, gold, silver, copper, tungsten, aluminium, aluminium alloy, etc. As a method of film formation, sputtering or vacuum deposition is used, the cathode 27 typically having a thickness of approximately 50 nm to 500 nm.

The bank 28 is a structure required to fill areas with a sufficient amount of a solution containing material of the light-emitting layer 25, and is formed into a predefined shape by photolithography. According to the shape of the bank 28, shapes of sub-pixels of an organic EL light-emitter can be controlled.

The following describes an arrangement of RGB sub-pixels within pixels in the EL display device according to one embodiment of the present technology.

FIG. 4 is a diagram illustrating an arrangement of RGB sub-pixels within pixels in the EL display device according to one embodiment of the present technology. FIG. 4 illustrates a two-by-four array of eight pixels 50. Each of the pixels 50 includes four sub-pixels: sub-pixels 51R, 51G, 51B, and a pale blue (b) sub-pixel 51b. In the pixels 50 that are adjacent in a longitudinal direction, the light-emitting layers of the sub-pixels 51R, 51G, 51B, 51b that are adjacent are formed within first coupled bank areas 52 that each have an elongated shape corresponding to an area defined by the bank of two sub-pixels. In other words, the first coupled bank areas 52 are each areas corresponding to two sub-pixels. A plurality of pixels are formed across an entire panel according to combinations of the sub-pixels 51R, 51G, 51B, 51b in which the light-emitting layers are formed in the first coupled bank areas 52. The light-emitting layers of a portion of the sub-pixels 51G, 51B of the pixels 50 at upper and lower ends of the panel are formed within individual bank areas 53 each having an area of one sub-pixel.

Referring to EL display devices in which light-emitting layers are formed by using an inkjet method, which is a printing method, when pixel size is reduced for higher definition, RGB sub-pixel size also decreases. Thus, forming the light-emitting layers within areas defined by the bank with high accuracy becomes difficult, leading to occurrences of solutions of light-emitting material that forms the light-emitting layers spilling over the bank and colors mixing within sub-pixels.

However, according to the present technology, the light-emitting layers of the sub-pixels 51R, 51G, 51B, 51b that are adjacent are formed within the first coupled bank areas 52 each having an elongated shape and corresponding to an area defined by the bank of two sub-pixels. Thus, by using the first coupled bank areas 52, the technical problem of the solution containing the light-emitting material of the light-emitting layers spilling over is reduced, avoiding color mixing between the sub-pixels.

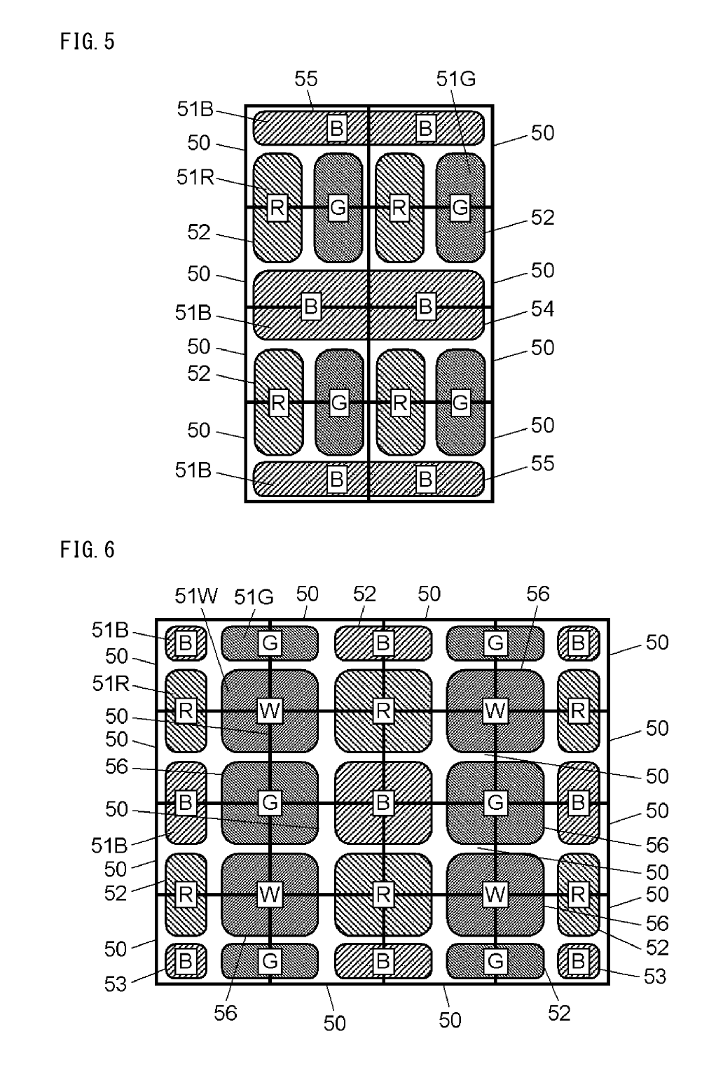

FIG. 5 is a diagram illustrating an example of another arrangement of RGB sub-pixels within pixels in the EL display device according to the present technology. FIG. 5 illustrates a two-by-four array of eight pixels 50. Each of the pixels 50 includes three sub-pixels: sub-pixels 51R, 51G, 51B. The light-emitting layers of the sub-pixels 51R, 51G that are adjacent in the longitudinal direction are formed within the first coupled bank areas 52 each having an elongated shape corresponding to an area defined by the bank of two sub-pixels. The light-emitting layers of the sub-pixels 51B that are adjacent in the longitudinal direction and a lateral direction are formed within a second coupled bank area 54 corresponding to an area defined by the bank of eight sub-pixels. The light-emitting layers of a portion of the sub-pixels 51B of the pixels 50 at upper and lower ends of the panel are formed within third coupled bank areas 55 each corresponding to an area defined by the bank of four sub-pixels.

FIG. 6 is a diagram illustrating an example of another arrangement of RGB sub-pixels within pixels in the EL display device according to the present technology. FIG. 6 illustrates a four-by-four array of sixteen pixels 50. Each of the pixels 50 includes four sub-pixels: the RGB sub-pixels 51R, 51G, 51B and white (W) sub-pixels 51W. The light-emitting layers of the sub-pixels 51R, 51G, 51B, 51W that are adjacent are formed within fourth coupled bank areas 56 each corresponding to an area defined by the bank of four sub-pixels.

In the pixels 50 at upper, lower, left, and right ends of the panel the light-emitting layers are formed within the first coupled bank areas 52, each having an elongated shape corresponding to an area defined by the bank of two sub-pixels in the longitudinal direction or the lateral direction. In the pixels 50 at corners of the panel, the light-emitting layers are formed within the individual bank areas 53 each having an area of one sub-pixel.

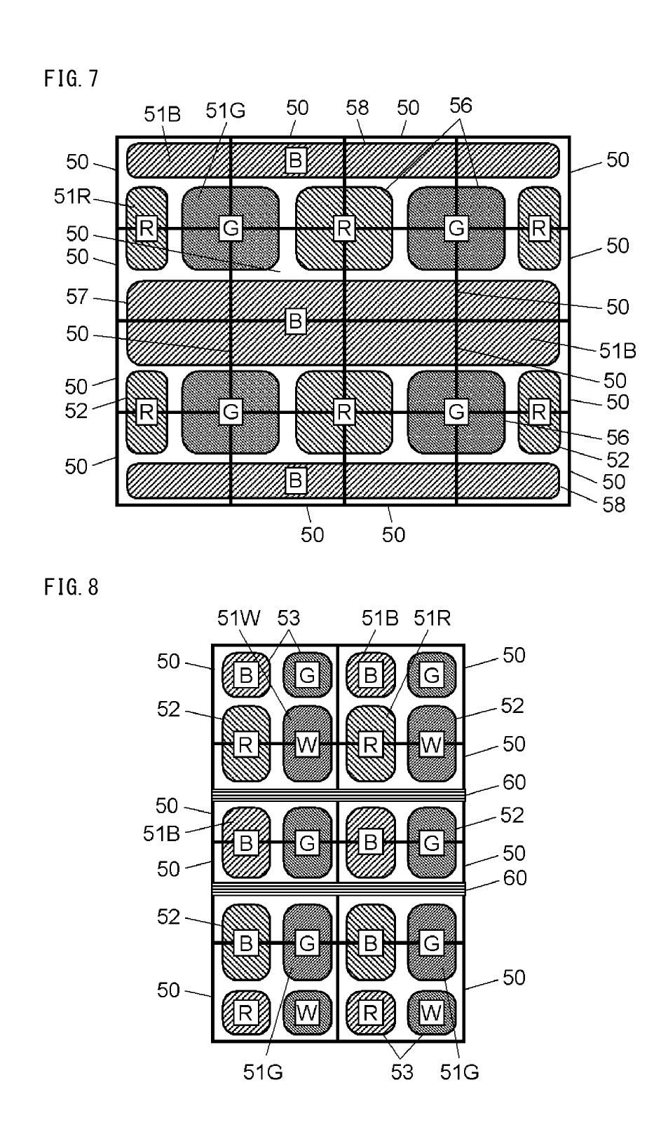

FIG. 7 is a diagram illustrating an example of another arrangement of RGB sub-pixels within pixels in the EL display device according to the present technology. FIG. 7 illustrates a four-by-four array of sixteen pixels 50. In FIG. 7, the sub-pixels 51W are not used and each of the pixels 50 includes three sub-pixels: the RGB sub-pixels 51R, 51G, 51B. The light-emitting layers of the sub-pixels 51R, 51G that are adjacent are formed within the fourth coupled bank areas 56 each corresponding to an area defined by the bank of four sub-pixels. The light-emitting layers of the sub-pixels 51B are formed within a fifth coupled bank area 57 corresponding to an area defined by the bank of a combination of four of the fourth coupled bank areas 56 that are adjacent in the lateral direction, each of which corresponds to an area defined by the bank of four sub-pixels.

Regarding the pixels 50 at upper, lower, left, and right ends of the panel, the light-emitting layers of the sub-pixels 51R or the sub-pixels 51G (in FIG. 7 the sub-pixels 51R) are formed within the first coupled bank areas 52 each having an elongated shape corresponding to an area defined by the bank two sub-pixels in the longitudinal direction; and the light-emitting layers of the sub-pixels 51B are formed within sixth coupled bank areas 58 each having an elongated shape corresponding to an area defined by the bank of eight sub-pixels in the lateral direction.

FIG. 8 is a diagram illustrating an example of another arrangement of RGB sub-pixels within pixels in the EL display device according to the present technology. FIG. 8 illustrates an example configuration in which, compared to FIG. 4, the sub-pixels 51b that are pale blue are replaced by the sub-pixels 51W that are white, so that the configuration is composed of the RGB sub-pixels 51R, 51G, 51B and the sub-pixels 51W. Further, referring to a large screen panel composed of a plurality of areas, FIG. 8 illustrates an example in which bus electrodes 60 are disposed between or within the pixels 50 in order to electrically connect each of the areas. Configuration of the bank is the same as the example illustrated in FIG. 4.

In the examples of arrangement illustrated in FIGS. 5-8, as with the example of arrangement illustrated in FIG. 4, the light-emitting layers of adjacent ones of the sub-pixels 51R, 51G, 51B, 51b, 51W are formed within the first coupled bank areas 52, the second coupled bank area 54, . . . , the sixth coupled bank areas 58, each of which corresponds to areas defined by the bank of two to sixteen sub-pixels. Thus, the technical problem of the solution containing the light-emitting material of the light-emitting layers spilling over is reduced, avoiding color mixing between the sub-pixels.

Specifically, in the case of the individual bank areas 53, when a lateral width thereof is 57 μm, for example, a longitudinal direction of one of the first coupled bank areas 52 has a length of approximately 121 μm, being at least double that of a lateral direction thereof. When the light-emitting layers are formed by an inkjet method it becomes possible for color mixing to be avoided and coating to be divided up appropriately.

Further, a number of drops of solution of the organic material ejected within an area defined by the bank can be increased because of an increase in size of the areas defined by the bank. Thus, compared to a case in which the number of drops is low, variability of drop quantity is reduced, variability of film thickness of the light-emitting layers due to variability of the drop quantity is reduced, and variability of light-emitting properties is reduced.

According to the present technology, in the pixels of the light emitters, adjacent sub-pixels of an identical color are formed by positioning the light-emitting layers within coupled bank areas each corresponding to an area defined by the bank of at least two sub-pixels. Thus, the EL display device having high definition can easily be implemented. The embodiments above describe top-emission types that are easy to implement at high definitions, but the present technology is also effective with respect to bottom emission types. Further, the present technology may also be applied to the EL display device having light emitters formed without a bank, as long as the sub-pixels of identical colors that are adjacent can be formed by arrangement of light emitting layers each having an area corresponding to an area of at least two sub-pixels.

Embodiments are described above as examples of the technology in the present disclosure. For this purpose, the attached drawings and detailed description are provided.

Accordingly, the elements disclosed in the attached drawings and the detailed description include not only elements required to solve the technical problem, but also elements to illustrate the above technology that are not essential to solve the technical problem. Thus, the disclosure in the attached drawings and the detailed description of the elements that are not essential should not be considered to make the elements essential.

Further, the embodiments above are for illustrating the technology of the present disclosure, and therefore various modifications, replacements, additions, omissions, etc., are possible within the scope of the claims or equivalents thereof.

### INDUSTRIAL APPLICABILITY

The present technology is applicable to easy implementation of the EL display device having high definition.

### REFERENCE SIGNS LIST

1 thin film transistor array
2 anode
3 light-emitting layer
3 cathode
4 pixels
5 pixel circuit
6 gate lines
8 source lines
9 power supply lines
10, 11 thin film transistor
21 base substrate
22 thin film transistor array
23 anode
24 hole transport layer
25 light-emitting layer
26 electron transport layer
27 cathode
28 bank
29 sealing layer
30 adhesive layer
31 sealing substrate
50 pixels
51R, 51G, 51B, 51b, 51W sub-pixels
52 first coupled bank areas
53 individual bank areas
54 second coupled bank area
55 third coupled bank areas
56 fourth coupled bank areas
57 fifth coupled bank area
58 sixth coupled bank areas

1. An electroluminescence (EL) display device comprising:
a light emitter in which an array of pixels are arranged, each of the pixels including sub-pixels configured to emit at least red, green, and blue light; and
a thin film transistor array configured to control light emission of the light emitter, wherein
among the sub-pixels, sub-pixels that are adjacent and configured to emit identical colors include a light-emitting layer having an area corresponding to at least an area of two of the sub-pixels.

2. An electroluminescence (EL) display device comprising:
a light emitter in which an array of pixels are arranged, each of the pixels including sub-pixels configured to emit at least red, green, and blue light; and
a thin film transistor array configured to control light emission of the light emitter, wherein
the sub-pixels include light-emitting layers, the light-emitting layers being configured to emit at least red, green, and blue light and being disposed within areas defined by a bank having a lattice shape, and
among the sub-pixels, sub-pixels that are adjacent and configured to emit identical colors include one of the light-emitting layers disposed within a coupled bank area, the coupled bank area corresponding to an area defined by the bank of at least two of the sub-pixels.

3. The EL display device of claim 2, wherein
the light-emitting layer of sub-pixels that are adjacent in a vertical direction and configured to emit red/green light is disposed within a first coupled bank area, the first coupled bank area having an elongated shape and corresponding to an area defined by the bank of two of the sub-pixels, and
the light-emitting layer of sub-pixels that are adjacent in the vertical direction and a lateral direction and configured to emit blue light is disposed within a second coupled bank area, the second coupled bank area having an area defined by the bank of eight of the sub-pixels.

4. The EL display device of claim 2, wherein
the light-emitting layer of sub-pixels that are adjacent is disposed within a fourth coupled bank area, the fourth coupled bank area corresponding to an area defined by the bank of four of the sub-pixels.

5. The EL display device of claim 2, wherein
the light-emitting layer of sub-pixels that are adjacent is disposed within a fourth coupled bank area, the fourth coupled bank area corresponding to an area defined by the bank of four of the sub-pixels, and
the light-emitting layer of sub-pixels configured to emit blue light is disposed within a fifth coupled bank area, the fifth coupled bank area corresponding to an area defined by the bank of four of the fourth coupled bank areas that are adjacent in a lateral direction.
